(19) United States
(12) Patent Application Publication
(10) Pub. No.: US 2007/0158714 A1
(43) Pub. Date: Jul. 12, 2007

(54) ONE-MASK HIGH-K METAL-INSULATOR-METAL CAPACITOR INTEGRATION IN COPPER BACK-END-OF-LINE PROCESSING

(75) Inventors: Ebenezer E. Eshun, Wappingers Falls, NY (US); Jessie Fortune Abbotts, Fletcher, VT (US); Daniel W. Colello, Burlington, VT (US); Douglas Duane Coolbaugh, Essex Junction, VT (US); Zhong-Xiang He, Essex Junction, VT (US); Matthew David Moon, Jeffersonville, VT (US); Charles Francis Musante, South Burlington, VT (US); Robert Mark Rassel, Colchester, VT (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 11/164,382

(22) Filed: Nov. 21, 2005

(51) Int. Cl. H01L 29/94

(52) U.S. Cl. 257/295

(57) ABSTRACT

A MIM capacitor technique is described wherein bottom plates (electrodes) are composed of gate conductor material, and are formed in the same layer, in the same way, using the same masking and processing steps as transistor gates. The top plates (electrodes) are formed using a simple single-mask, single-damascene process. Electrical connections to both electrodes of the MIM capacitor are made via conventional BEOL metallization, requiring no additional dedicated process steps. The bottom plates (formed of gate conductor material) of the MIM capacitors overlie STI regions formed at the same time as STI regions between transistors. Method and apparatus are described.

### TECHNICAL FIELD

The present invention relates to semiconductor processing, and more particularly to the formation of integrated capacitors in semiconductor devices.

### BACKGROUND ART

Metal-Insulator-Metal (MIM) capacitors have become essential components of high-frequency/RF (Radio Frequency)/Analog integrated circuitry because of their low parasitic coupling to their underlying silicon substrate, their excellent voltage coefficient, and their ability to operate at relatively higher voltages than other types of integrated capacitors.

Typically, prior-art MIM capacitors are formed in BEOL (Back End Of Line) metal levels as shown and described hereinbelow with respect to FIGS. 1A-1D. FIG. 1A is a cross-sectional view of a prior-art starting structure 100A for forming a MIM capacitor. In FIG. 1A, a first metal layer 102, an overlying dielectric film 104, a second metal layer 106 overlying the dielectric film 104, and an etch stop film 108 overlying the second metal layer 106 have been provided. The first metal layer 102 forms a bottom electrode (plate) of the MIM capacitor. The second metal layer 106 will be patterned to form the top electrode (plate) of the MIM capacitor. As the “BEOL” designation implies, the structure of FIG. 1A is formed on a semiconductor device after first metallization, i.e., after all of the underlying active electronic devices have been formed.

FIG. 1B is a cross-sectional view of a prior-art structure 100B formed by processing the structure shown and described hereinabove with respect to FIG. 1A. First, the etch-stop film layer 108 is patterned to form a patterned etch stop film 108B, then a reactive ion etch (RIE) process is used to form a top electrode 106B of the MIM capacitor. The dielectric film 104 of FIG. 1A is eroded somewhat in the etched-away areas to form the etched dielectric film shown as 104B in FIG. 1B.

FIG. 1C is a cross-sectional view of a completed prior-art MIM capacitor structure 100C. This structure is created by forming a top-electrode contact structure 110A (+) connecting to the top electrode (plate) 106B and by forming bottom electrode contact structures 110B (−) and 110C (−) connecting to the bottom electrode (plate) 102. Typically, a damascene or dual-damascene process is used to form the contact structures 110A, 10B and 110C.

FIG. 1D is a cross-sectional view of a typical completed prior-art semiconductor device 100D embodying a MIM capacitor 100C of the type shown and described hereinabove with respect to FIG. 1C. In FIG. 1D, a typical prior-art semiconductor device 100D is formed on a semiconductor substrate 120. Active components are formed in the substrate 120 and conductive connections and a planarizing BPSG layer 122 are formed. A first metallization layer 124 (M1) is formed above the BPSG layer, competing the “FEOL” (Front-End-Of-Line) processing (i.e., processing up to and including first metallization) of the device 100D. The MIM capacitor 100C is formed in a second metallization layer 126 (M2). A third metallization layer 128 (M3) is formed atop the second metallization layer 126. Each of the three metallization layers 124, 126 and 128 is characterized by a Low-K dielectric. A last metallization layer 130 (LM) is characterized by undoped silicate glass (USG). Copper interconnect 132 is used throughout the metallization layers 124, 126, 128 and 130. Aluminum contact pads 134 provide external electrical connections to the underlying wiring layers.

The prior-art MIM capacitor shown and described hereinabove with respect to FIGS. 1A-1D is generally cumbersome and expensive to produce due to the need for three lithographic patterning process. Two lithographic masks are used to pattern the top and bottom plates and a third mask is used as an alignment aid. This greatly complicates the BEOL processing of semiconductor devices that employ such MIM capacitors.

Several prior-art MIM capacitor techniques have been developed to address some of the difficulties associated with producing MIM capacitors.

US Patent Application Publication 2005/0020066 A1 (Jeong-Sik Choi et.al.), incorporated herein by reference, describes a capacitor structure wherein a metal silicide layer is formed on a top surface of a conductive plug. The conductive plug extends downward from the metal silicide layer to a bottom electrode of the capacitor, forming an ohmic electrical connection therebetween.

US Patent Application Publication 2004/0063295 A1 (Chambers et al., assigned to Intel Corporation), incorporated herein by reference, describes a capacitor wherein a bottom plate is formed in a dielectric layer by means of a damascene trenching technique. A dielectric film is then deposited over the dielectric layer, covering the bottom plate. A top plate of the capacitor is then formed as part of a patterned conductive layer deposited atop the dielectric film.

U.S. Pat. No. 6,583,491 (Huang et al., assigned to Taiwan Semiconductor Manufacturing Company), incorporated herein by reference, describes a structure wherein a MIM (Metal-Insulator-Metal) capacitor is formed in a semiconductor device atop a conductive stud that extends into lower circuit layers of the device, connecting a bottom plate of the MIM capacitor thereto.

US Patent Application Publication 2002/0019123 A1 (Ma et al., assigned to Taiwan Semiconductor Manufacturing Company), incorporated herein by reference, describes a MIM capacitor structure wherein the capacitor and thick metal inductors are fabricated simultaneously. A first plate of the capacitor is formed in a first level wiring layer. A damascene trenching technique is then used to form a second metal plate of the capacitor and a dielectric layer between the plates.

US Patent Application Publication 2002/00146646 A1 (Tsu et al., assigned to Texas Instruments Incorporated), incorporated herein by reference, describes a capacitor structure wherein a dielectric layer and a metal top capacitor plate are formed over and around a raised base electrode structure (bottom plate). The base electrode structure is formed above (adjacent to) an insulating dielectric layer.

### SUMMARY OF THE INVENTION

It is therefore an object of the present inventive technique to provide a MIM integrated capacitor that is compatible with Cu BEOL processes.

It is another object of the present inventive technique to reduce complexity of integrating MIM into BEOL processes

It is another object of the present inventive technique to reduce the number of processing steps required to form MIM capacitors.

It is a further object of the present invention to provide a simplified single-mask technique for forming a MIM integrated capacitor.

Other objects, features and advantages of the inventive technique will become evident in light of the ensuing description thereof.

According to the invention, MIM capacitors are produced where bottom plate (electrode) is composed of gate conductor material, and is formed in the same layer, in the same way, using the same masking and processing steps as transistor gates. The top plates of the MIM capacitors (electrodes) are formed using a simple single-mask, single-damascene process. Electrical connections to both electrodes of the MIM capacitor are made via conventional BEOL metallization, and require no dedicated process steps. The bottom plates (formed of gate conductor material) of the MIM capacitors overlie STI regions that isolate them from the substrate. Like the bottom plates themselves, the STI regions for MIM capacitors are formed using the same process steps at the same time as STI regions between transistors.

According to an aspect of the invention, since the bottom plates (electrodes) are formed of the gate conductor material, wherever a direct connection is desired between a transistor gate and a bottom plate (electrode) is desired, the bottom plate can be formed as a lateral extension of a transistor's gate conductor. When such a connection is not desired, the MIM bottom plates can be can formed overlying dedicated STI regions as isolated “islands” of gate conductor material. According to the invention, the inventive MIM capacitor comprises a capacitor bottom electrode formed of a gate conductor material in a gate conductor layer of the semiconductor device. A shallow trench isolation (STI) region underlies the bottom electrode. A trench in a first dielectric layer overlying the gate conductor layer is lined with a Hi-K dielectric film, and the trench is filled with metal to form the top electrode of the capacitor. The Hi-K dielectric film forms the capacitor's dielectric between the top and bottom electrodes. Preferably, the top electrode is Cu (Copper) and a liner layer of e.g., tantalum nitride (TaN) is used between the Hi-K dielectric and the top electrode.

According to an aspect of the invention, after forming the capacitors, conventional BEOL metallization techniques can be employed to form electrical connections to the top and bottom electrodes of the capacitors. Specifically, openings formed in a metallization dielectric layer extend downward to the top electrodes. These opening are filled with metal, preferably copper (Cu), to form electrical connections thereto.

According to another aspect of the invention, a conductive stud is formed through the first dielectric layer to make electrical connection to the bottom electrode structure. An opening is formed extending through the metallization dielectric layer to the conductive stud and is filled with metal, preferably copper (Cu), to form an electrical connection thereto.

According to an aspect of the invention, the bottom electrode structure can be formed as a lateral extension of a transistor's gate conductor whenever a direct connection between a transistor gate and a capacitor bottom electrode is desired. Alternatively, the bottom electrode can be formed as an independent “island” of gate conductor material overlying a STI region, separate from any other gate conductor material in the gate conductor layer.

According to various aspects of the invention, the gate conductor material can be polysilicon, silicided polysilicon or a silicided metal, e.g., cobalt silicide (CoSiₓ).

The present inventive technique also includes a method for forming MIM capacitors. First, a shallow trench isolation (STI) region is formed in a semiconductor substrate. The MIM capacitor is formed overlying this STI region. A capacitor bottom electrode structure is formed as part of a gate conductor layer overlying the shallow trench isolation region, said bottom plate electrode being composed of gate conductor material. A protective film layer is formed over the gate conductor layer. A first dielectric layer is formed and planarized over the gate conductor layer. A trench is formed through the first dielectric layer and protective film layer to expose a portion of the bottom plate electrode structure. A Hi-K dielectric film is deposited over the first dielectric layer, coating exposed trench surfaces. A liner material is disposed over the Hi-K dielectric film, coating the surface thereof including portions of the Hi-K dielectric film on trench surfaces. A metal layer is deposited over the liner material such that the metal layer overfills the trench. Then the metal layer, liner layer and Hi-K dielectric film are planarized back to the level of the first dielectric layer (preferably using a chem-mech polishing technique) such that a remaining portion of the metal layer forms a top electrode of the MIM capacitor and the remaining Hi-K dielectric film forms a dielectric between the top electrode and the bottom electrode structure.

Another aspect of the present inventive method is directed to forming a conductive stud extending from the bottom electrode structure through the first dielectric layer and generally flush with a top surface thereof.

Another aspect of the present inventive method is directed to forming electrical connections to the top and bottom electrodes by forming a metallization dielectric layer over the first dielectric layer, forming an opening extending through the metallization dielectric layer to the conductive stud, and filling the opening with metal to form an electrical connection to the conductive stud. Electrical connections to the top electrode are similarly formed by forming at least one opening extending through the metallization dielectric layer to the top electrode of the MIM capacitor and filling the opening with metal to provide an electrical connection to the top electrode of the MIM capacitor.

### BRIEF DESCRIPTION OF THE DRAWINGS

These and further features of the present invention will be apparent with reference to the following description and drawing, wherein:

FIG. 1A is a cross-sectional view of a starting structure for forming a MIM capacitor, in accordance with the prior art.

FIG. 1B is a cross-sectional view of a structure formed after processing of the structure of FIG. 1A, in accordance with the prior art.

FIG. 1C is a cross-sectional view of a completed MIM capacitor structure, in accordance with the prior art.

FIG. 1D is a cross-sectional view of a completed semiconductor device embodying the MIM capacitor of FIG. 1C, in accordance with the prior art.

FIG. 2A is cross-sectional view of a semiconductor device at a stage of processing where FEOL processing has been completed, in accordance with the invention.

FIG. 2B is a cross-sectional view of the semiconductor device of FIG. 2A after a first set of processing steps, in accordance with the invention.

FIG. 2C is a cross-sectional view of the semiconductor device of FIG. 2B after a second set of processing steps, in accordance with the invention.

FIG. 2D is a cross-sectional view of the semiconductor device of FIG. 2C after a third set of processing steps, in accordance with the invention.

FIG. 2E is a cross-sectional view of the semiconductor device of FIG. 2D after a fourth set of processing steps, in accordance with the invention.

FIG. 2F is a cross-sectional view of the semiconductor device of FIG. 2E after a fifth set of processing steps, showing a completed MIM capacitor, in accordance with the invention.

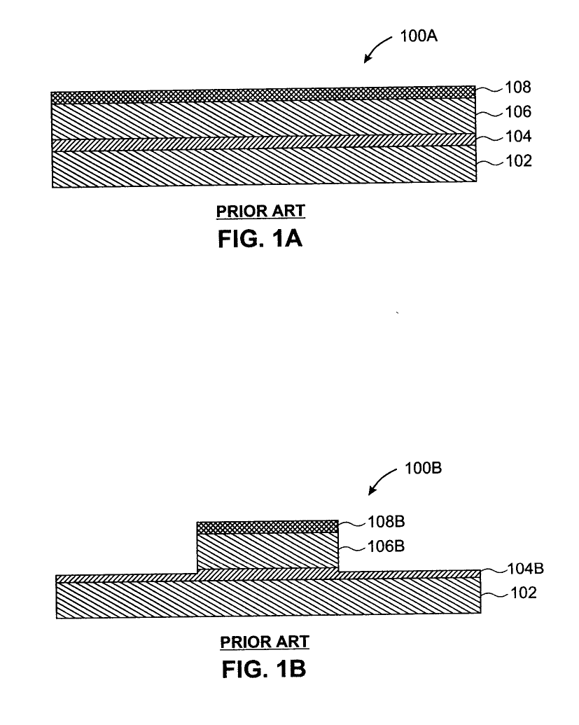

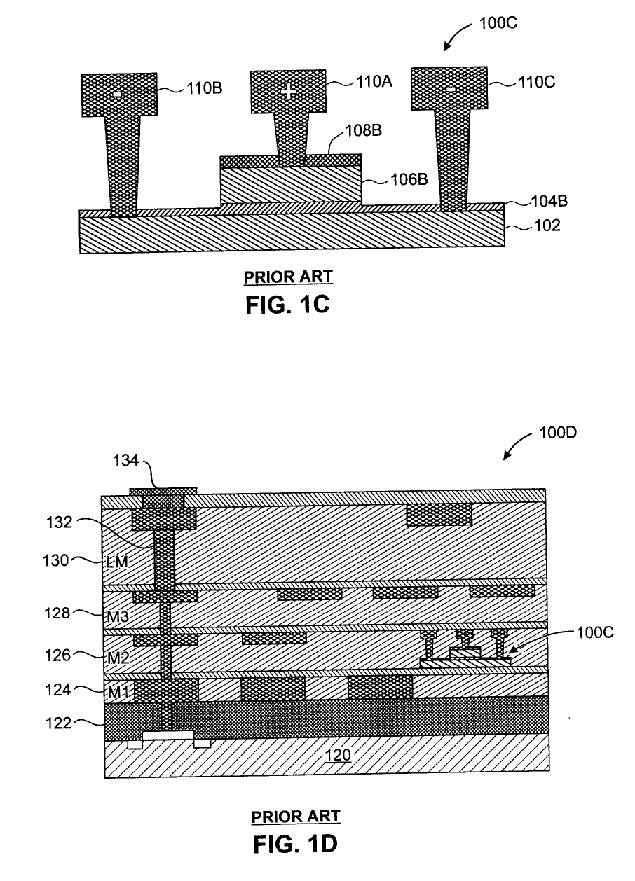

### DETAILED DESCRIPTION OF THE INVENTION

The present inventive technique produces MIM capacitors whose bottom plate (electrode) is composed of gate conductor material, and is formed in the same layer, in the same way, using the same masking and processing steps as transistor gates. The top plate (electrodes) are formed using a simple single-mask, single-damascene process. Electrical connections to both electrodes of the MIM capacitor are made via conventional BEOL metallization, and require no dedicated process steps. These features of the present inventive technique greatly simply and reduce the cost of production of integrated MIM capacitors. The bottom plates (formed of gate conductor material) of the MIM capacitors overlie STI regions. Like the bottom plates themselves, the STI regions for MIM capacitors are formed using the same process steps at the same time as STI regions between transistors.

A unique characteristic of the present inventive technique is that the present inventive MIM capacitor formation bridges FEOL (Front-End Of Line) and BEOL (Back-End Of Line) processes, and as such might be considered a “Middle of Line” or MOL process.

Since the bottom plates (electrodes) of the present MIM capacitors are formed of the gate conductor material, where a direct connection is desired between a transistor gate and a bottom plate (electrode) is desired, the bottom plate can be formed as a lateral extension of a transistor's gate conductor. When such a connection is not desired, the MIM bottom plates can be can formed overlying dedicated STI regions as isolated “islands” of gate conductor material not connected to any transistor's gate conductor.

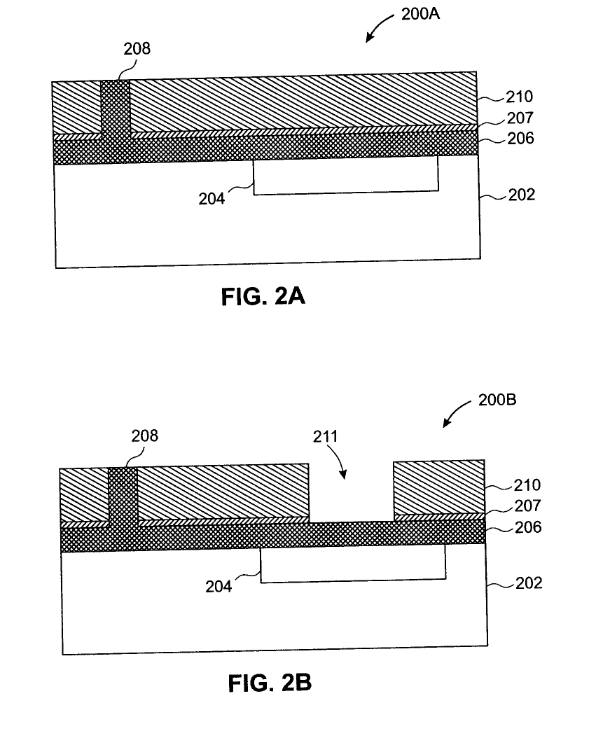

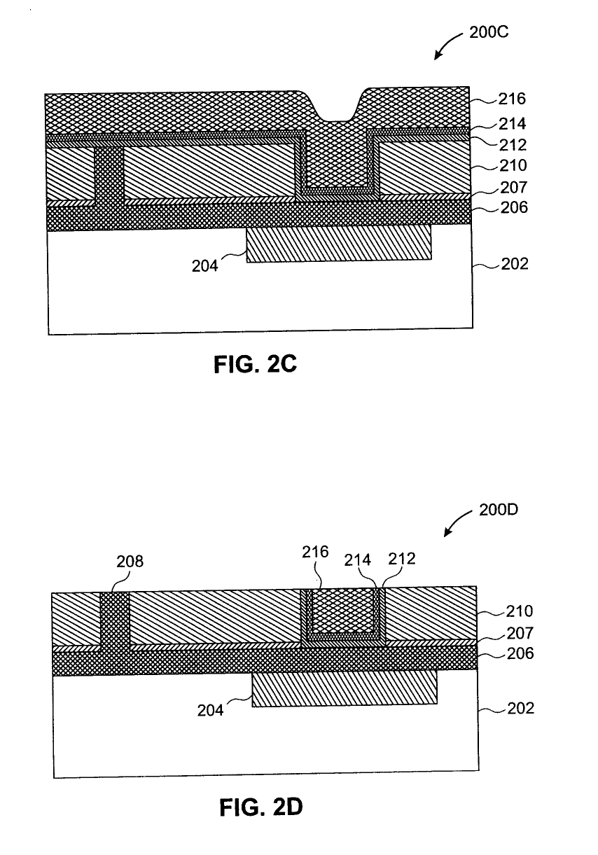

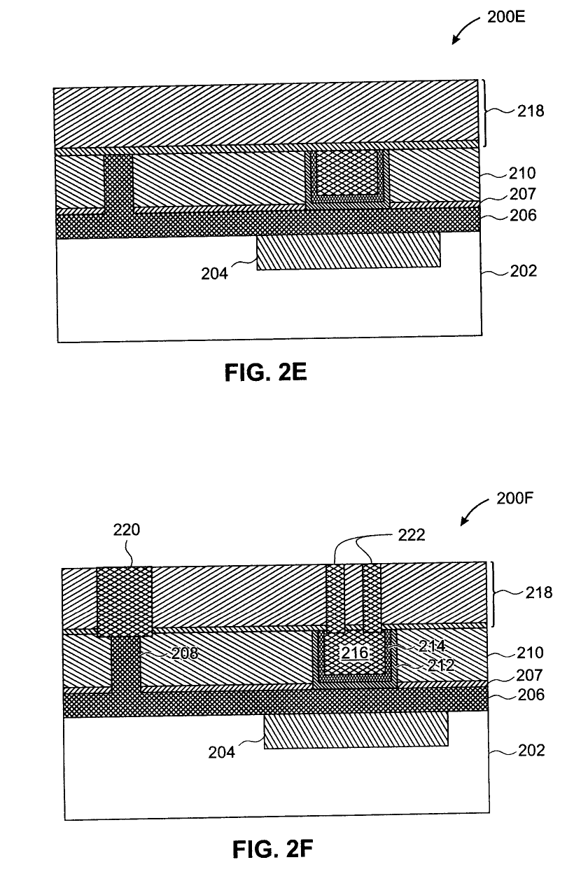

The present inventive MIM capacitor technique and the method used to form it are now described with respect to FIGS. 2A-2F.

FIG. 2A is cross-sectional view of a typical semiconductor device 200A at a final stage of FEOL processing, according to the present inventive technique. At this stage, a semiconductor substrate 202 has been processed to form active electronic devices (e.g., transistors) therein. Gate conductor material 206 has been patterned. A protective dielectric film layer 207 of silicon nitride (Si₃N₄) has been deposited over the gate conductor material 206 and a planarizing layer 210 of BPSG (boro-phospho-silicate glass) has been formed. A conductive access stud 208 has been formed through an opening in the BPSG layer 210 and silicon nitride dielectric film 207 to contact the gate conductor material 206, providing electrical connectivity to the gate conductor material 206 through the BPSG layer 210. Preferably the gate conductor material is polysilicon, silicided polysilicon or a silicided metal (e.g., cobalt silicide CoSiₓ), which are all conventional gate conductor materials compatible with prior-art semiconductor processes.

In preparation for formation of a MIM capacitor, the gate conductor material 206 has been patterned to form a bottom plate (electrode) over a shallow trench isolation (STI) region 204.

FIG. 2B is a cross-sectional view of a semiconductor device 200B resulting from processing the semiconductor device 200A of FIG. 2A according to a first set of processing steps to form a trench 211, in accordance with the invention. In FIG. 2B, the trench 211 has been formed by a suitable lithographic etch process (e.g., lithographically patterned mask, then etch and clean). The trench 211 extends through the BPSG layer 210 and silicon nitride film layer 207 to expose a bottom plate portion of the gate conductor material 206 over the STI region 204. The exposed portion of the gate conductor 206 becomes the bottom plate (electrode) of the MIM capacitor.

FIG. 2C is a cross-sectional view of a semiconductor device 200C resulting from processing the semiconductor device 200B of FIG. 2B according to a second set of processing steps, in accordance with the invention. In FIG. 2C, a first half of a damascene process that will form a dielectric and top plate (electrode) of the MIM capacitor is begun. First, a Hi-K dielectric film layer 212 is deposited over the device 200B (FIG. 2B) coating the “walls” and “floor” of the trench 211. Next a liner layer 214 is deposited over the Hi-K dielectric film layer 212. Finally, metal conductor material 216 is deposited over the device, filling the trench and covering the Hi-K dielectric film layer 212 and the liner layer 214. Preferably, the metal conductor material is Cu (copper) and the liner layer is TaN (tantalum nitride).

FIG. 2D is a cross-sectional view of a semiconductor device 200D resulting from processing the semiconductor device 200C of FIG. 2C after a third set of processing steps complete the damascene process to form the MIM capacitor's dielectric and top plate (electrode), in accordance with the invention. A chem-mech polishing (CMP) process is used to planarize the semiconductor device 200D back to the level of the BPSG layer, thereby removing portions of the Hi-K dielectric film 212, liner layer 214 and metal conductor material 216 outside of the trench 211. After polishing, the remaining metal conductor material 216 in the trench forms the top plate (electrode) of the MIM capacitor, the remaining Hi-K dielectric film 212 in the trench forms the MIM capacitor's dielectric, and the gate conductor material 206 overlying the STI region 204 forms the bottom plate (electrode) of the MIM capacitor.

FIG. 2E is a cross-sectional view of a semiconductor device 200E resulting from depositing a metallization dielectric layer 218 (preferably a Low-K dielectric) over the semiconductor device 200D of FIG. 2D.

FIG. 2F is a cross-sectional view of a semiconductor device 200F resulting from forming metal conductors 220 and 222 to contact the conductive stud 208 and metal top plate 216 of the MIM capacitor formed in the semiconductor device 200E of FIG. 2E. The conductive stud 208 shown initially in FIG. 2A provides electrical access to the bottom plate (electrode) of the MIM capacitor in much the same manner as an electrical connection would be made to the gate of a transistor, and is formed by exactly the same processing steps at the same time. The conductors 220 and 222 are preferably formed in a damascene process as a part of conventional Cu BEOL processing. Those of ordinary skill in the art will immediately understand and appreciate that these conductors do not require any separate operations beyond those that would ordinarily be required for Cu BEOL metallization formed in the same layer at the same time.

One of the advantages of the present inventive technique is that the bottom plate of MIM capacitors is formed at the same time and from the same material as transistor gates. This means that no additional lithographic masking, etching or deposition steps are required to form the bottom plates of MIM capacitors. The STI regions underlying MIM capacitors are preferably formed at the same time as STI regions between transistors. Further, the MIM capacitor bottom plates (electrodes) need not be directly connected to a gate of a transistor. Those of ordinary skill in the art will immediately understand and appreciate that the gate-level masking used to form transistor gates can readily be adapted to include both gate-connected bottom electrode regions and isolated bottom electrode regions that can be connected to other circuit elements via subsequent BEOL metallization.

Further, the formation of the electrical connections 220, 222 to the MIM capacitor is accomplished in the normal course of Cu BEOL processing, requiring no extra steps. The only additional steps required to form the present inventive MIM capacitor relate to the formation of the top electrode trench (211, FIG. 2B). A single lithographic mask is used to form the trench. The remainder of the processing to form the MIM capacitor's dielectric and top electrode involve simple single-damascene steps of “blanket” deposition and chem-mech polishing/planarization.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described inventive components the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. An integrated MIM capacitor in a semiconductor device, comprising:
a capacitor bottom electrode formed of a gate conductor material in a gate conductor layer of the semiconductor device;
a shallow trench isolation (STI) region underlying the bottom electrode;
a trench formed in a first dielectric layer overlying the gate conductor layer;
a Hi-K dielectric film lining side and bottom surfaces of the trench; and
a metal capacitor top electrode disposed in and filling the trench over the Hi-K dielectric film.

2. An integrated MIM capacitor according to claim 1, further comprising:
a liner material disposed in the trench between the capacitor top electrode and the Hi-K dielectric film.

3. An integrated MIM capacitor according to claim 2, wherein the liner material is tantalum nitride (TaN).

4. An integrated MIM capacitor according to claim 1, further comprising:
a metallization dielectric layer disposed over the first dielectric layer and the top electrode; and
metal conductors extending through the metallization dielectric layer to make contact with the top and bottom capacitor electrodes.

5. An integrated MIM capacitor according to claim 4, wherein the top electrode is Cu (copper).

6. An integrated MIM capacitor according to claim 1, wherein the bottom electrode is formed as a lateral extension of a transistor's gate conductor.

7. An integrated MIM capacitor according to claim 1, wherein the bottom electrode is formed separate from any other gate conductor material in the gate conductor layer.

8. An integrated MIM capacitor according to claim 1 wherein the gate conductor material is polysilicon.

9. An integrated MIM capacitor according to claim 1, wherein the gate conductor material is silicided polysilicon.

10. An integrated MIM capacitor according to claim 1, wherein the gate conductor material is a silicided metal.

11. An integrated MIM capacitor according to claim 1, wherein the gate conductor material is Cobalt Silicide (CoSiₓ).

12. A method of forming an integrated MIM capacitor, comprising the steps of:
forming a shallow trench isolation region in a semiconductor substrate;
forming a capacitor bottom electrode structure as part of a gate conductor layer overlying the shallow trench isolation region, said bottom plate electrode being composed of gate conductor material;
forming a protective film layer over the gate conductor layer;
forming and planarizing a first dielectric layer over the gate conductor layer;
forming a trench through the first dielectric layer and protective film layer to expose a portion of the bottom plate electrode structure;
depositing a Hi-K dielectric film over the first dielectric layer, coating exposed trench surfaces;
depositing a liner material over the Hi-K dielectric film, coating the surface thereof including portions of the Hi-K dielectric film on trench surfaces;
depositing a metal layer over the liner material such that the metal layer overfills the trench; and
planarizing the metal layer, liner layer and Hi-K dielectric film back to the level of the first dielectric layer such that a remaining portion of the metal layer forms a top electrode of the MIM capacitor and remaining Hi-K dielectric film forms a dielectric between the top electrode and the bottom electrode structure.

13. A method according to claim 12, further comprising the step of:
forming a conductive stud extending from the bottom electrode structure through the first dielectric layer and generally flush with a top surface thereof.

14. A method according to claim 13 further comprising the steps of:
forming a metallization dielectric layer over the first dielectric layer;
forming an opening extending through the metallization dielectric layer to the conductive stud; and
filling the opening with metal to form an electrical connection to the conductive stud.

15. A method according to claim 12, further comprising the steps of:
forming a metallization dielectric layer over the first dielectric layer;
forming at least one opening extending through the metallization dielectric layer to the top electrode of the MIM capacitor; and
filling the opening with metal to provide an electrical connection to the top electrode of the MIM capacitor.

16. A method according to claim 12, wherein the gate conductor material is polysilicon.

17. A method according to claim 12, wherein the gate conductor material is silicided polysilicon.

18. A method according to claim 12, wherein the gate conductor material is a silicided metal.

19. A method according to claim 12, wherein the gate conductor material is Cobalt Silicide (CoSiₓ).
